(19) United States
(12) Patent Application Publication
(10) Pub. No.: US 2026/0245602 A1
(43) Pub. Date: Aug. 20, 2026

(54) ZQ CALIBRATION CIRCUIT AND MEMORY DEVICE INCLUDING THE SAME

(71) Applicant: SAMSUNG ELECTRONICS CO., LTD., Suwon-si (KR)

(72) Inventors: Yeonwook JUNG, Suwon-si (KR); Donghyun KIM, Suwon-si (KR); Jungjune PARK, Suwon-si (KR); Jungmin SEO, Suwon-si (KR); Chiweon YOON, Suwon-si (KR); Junghoon JIN, Suwon-si (KR)

(73) Assignee: SAMSUNG ELECTRONICS CO., LTD., Suwon-si, Gyeonggi-do (KR)

(21) Appl. No.: 19/542,127

(22) Filed: Feb. 17, 2026

(30) Foreign Application Priority Data
Feb. 18, 2025 (KR) 10-2025-0021080

(51) Int. Cl. G11C 7/10; G11C 5/14; G11C 16/04; H03K 19/00; H10W 90/24; H10W 90/26

(52) U.S. Cl. CPC G11C 7/1048; G11C 5/14; H03K 19/0005; G11C 16/0483; G11C 2207/2254; H10W 90/24; H10W 90/26

(57) ABSTRACT

A ZQ calibration circuit includes first and second ZQ drivers and first and second ZQ calibrators. The first ZQ driver is connected between a first voltage and a first node, and its impedance is adjusted based on a first calibration code. The first ZQ calibrator is connected to the first node, receives a first reference voltage, and generates the first calibration code by performing a calibration operation based on a voltage at the first node and the first reference voltage. The second ZQ driver is connected between the first node and a ZQ pad, and its impedance is adjusted based on a second calibration code. The second ZQ calibrator is connected to the ZQ pad, receives a second reference voltage, and generates the second calibration code by performing a calibration operation based on a voltage at the ZQ pad and the second reference voltage. The two calibration operations are performed simultaneously.

### CROSS-REFERENCE TO RELATED APPLICATION

This application claims priority under 35 USC § 119 to Korean Patent Application No. 10-2025-0021080 filed on Feb. 18, 2025 with the Korean Intellectual Property Office (KIPO), the contents of which are herein incorporated by reference in their entirety.

### BACKGROUND

### 1. Technical Field

Example embodiments relate generally to semiconductor integrated circuits, and more particularly to ZQ calibration circuits and memory devices including the ZQ calibration circuits.

### 2. Description of the Related Art

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power. While volatile memory devices may perform read and write operations at a high speed, contents stored therein may be lost at power-off. Since nonvolatile memory devices retain contents stored therein even at power-off, they may be used to store data that needs to be retained.

A swing width of signals is decreasing to minimize a transmission time of signals interfacing between semiconductor memory devices. As the swing width of the signals decreases, an effect of external noise on the semiconductor memory devices increases, and signal reflection that may be caused by impedance mismatching in an interface may be a serious problem. To resolve the impedance mismatching, semiconductor memory devices may include ZQ pins to receive ZQ calibration commands from the outside of the semiconductor memory devices and perform ZQ calibration operations, thereby controlling impedance matching.

### SUMMARY

At least one example embodiment of the present disclosure provides a ZQ calibration circuit capable of efficiently performing a ZQ calibration operation.

At least one example embodiment of the present disclosure provides a memory device including the ZQ calibration circuit.

According to example embodiments, a ZQ calibration circuit includes a first ZQ driver, a first ZQ calibrator, a second ZQ driver and a second ZQ calibrator. The first ZQ driver is connected between a first voltage and a first node. An impedance of the first ZQ driver is adjusted based on a first calibration code. The first ZQ calibrator is connected to the first node, receives a first reference voltage, and generates the first calibration code by performing a first calibration operation based on a voltage at the first node and the first reference voltage. The second ZQ driver is connected between the first node and a ZQ pad. An impedance of the second ZQ driver is adjusted based on a second calibration code. The second ZQ calibrator is connected to the ZQ pad, receives a second reference voltage different from the first reference voltage, and generates the second calibration code by performing a second calibration operation based on a voltage at the ZQ pad and the second reference voltage. The first calibration operation and the second calibration operation are simultaneously performed.

According to example embodiments, a memory device includes a memory cell array, a first pad, a second pad and a ZQ calibration circuit. The first pad and the second pad input and output a first signal and a second signal, respectively. The first signal and the second signal are used for operating the memory cell array. The ZQ calibration circuit performs a ZQ calibration operation on the first pad and the second pad. The ZQ calibration circuit includes a first ZQ driver, a first ZQ calibrator, a second ZQ driver and a second ZQ calibrator. The first ZQ driver is connected between a first voltage and a first node. An impedance of the first ZQ driver is adjusted based on a first calibration code. The first ZQ calibrator is connected to the first node, receives a first reference voltage, and generates the first calibration code by performing a first calibration operation based on a voltage at the first node and the first reference voltage. The second ZQ driver is connected between the first node and a ZQ pad. An impedance of the second ZQ driver is adjusted based on a second calibration code. The second ZQ calibrator is connected to the ZQ pad, receives a second reference voltage different from the first reference voltage, and generates the second calibration code by performing a second calibration operation based on a voltage at the ZQ pad and the second reference voltage. The first calibration operation and the second calibration operation are simultaneously performed.

According to example embodiments, a ZQ calibration circuit includes a first ZQ driver, a first ZQ calibrator, a second ZQ driver and a second ZQ calibrator. The first ZQ driver operates based on a first power supply voltage, and includes a plurality of first transistors connected in parallel between the first power supply voltage and a first node. An impedance of the first ZQ driver is adjusted based on a first calibration code. The first ZQ calibrator is connected to the first node, receives a first reference voltage, and generates the first calibration code by performing a first calibration operation based on a voltage at the first node and the first reference voltage. The second ZQ driver operates based on a second power supply voltage having a voltage level lower than a voltage level of the first power supply voltage and equal to a voltage level of the first reference voltage, and includes a plurality of second transistors connected in parallel between the first node and a ZQ pad. An impedance of the second ZQ driver is adjusted based on a second calibration code. The second ZQ calibrator is connected to the ZQ pad, receives a second reference voltage different from the first reference voltage, and generates the second calibration code by performing a second calibration operation based on a voltage at the ZQ pad and the second reference voltage. When the first calibration operation is performed, the impedance of the first ZQ driver is adjusted by controlling on and off of each of the plurality of first transistors such that a voltage level of the voltage at the first node and the voltage level of the first reference voltage are equal to each other. When the second calibration operation is performed, the impedance of the second ZQ driver is adjusted by controlling on and off of each of the plurality of second transistors such that a voltage level of the voltage at the ZQ pad and a voltage level of the second reference voltage are equal to each other. During one ZQ interval based on one ZQ command, the first calibration operation and the second calibration operation are simultaneously performed.

The ZQ calibration circuit and the memory device according to example embodiments may include two or more ZQ drivers that operate based on different power supply voltages and are implemented with the stacked structure. In addition, the ZQ calibration circuit may include two or more ZQ calibrators for controlling two or more ZQ drivers, respectively. In the ZQ calibration circuit, two or more calibration operations may be substantially simultaneously performed using two or more ZQ drivers and two or more ZQ calibrators. Accordingly, two or more ZQ calibration operations may be performed rapidly and efficiently without increasing the execution time.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a ZQ calibration circuit according to example embodiments.

FIG. 2 is a diagram for describing an operation of a ZQ calibration circuit of FIG. 1.

FIGS. 3, 4 and 5 are diagrams illustrating examples of a ZQ calibration circuit of FIG. 1.

FIG. 6 is a block diagram illustrating a ZQ calibration circuit according to example embodiments.

FIG. 7 is a diagram for describing an operation of a ZQ calibration circuit of FIG. 6.

FIG. 8 is a block diagram illustrating a ZQ calibration circuit according to example embodiments.

FIG. 9 is a diagram for describing an operation of a ZQ calibration circuit of FIG. 9.

FIG. 10 is a block diagram illustrating a memory system according to example embodiments.

FIG. 11 is a block diagram illustrating a memory device according to example embodiments.

FIGS. 12A and 12B are diagrams for describing an operation of a memory device of FIG. 11.

FIG. 13 is a circuit diagram illustrating an equivalent circuit of a memory block included in a memory device of FIG. 11.

FIG. 14 is a block diagram illustrating a memory system according to example embodiments.

FIGS. 15A and 15B are diagrams illustrating examples of a memory package included in a memory system of FIG. 14.

FIGS. 16 and 17 are block diagrams illustrating a memory system according to example embodiments.

FIG. 18 is a flowchart illustrating a method of operating a ZQ calibration circuit according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

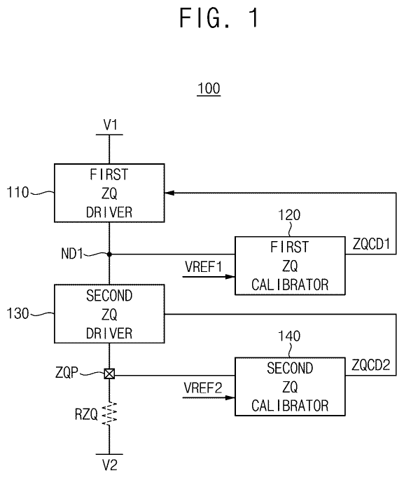

FIG. 1 is a block diagram illustrating a ZQ calibration circuit according to example embodiments.

Referring to FIG. 1, a ZQ calibration circuit 100 includes a first ZQ driver 110, a first ZQ calibrator 120, a second ZQ driver 130 and a second ZQ calibrator 140.

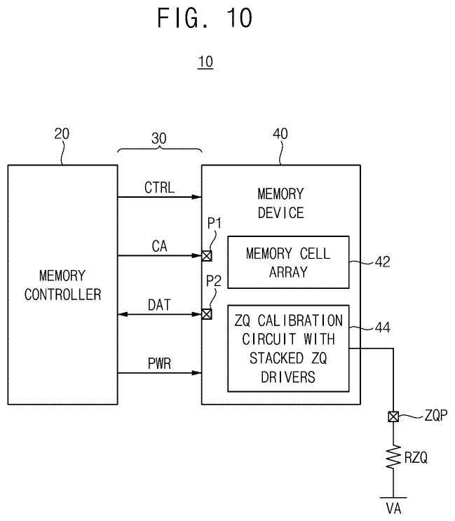

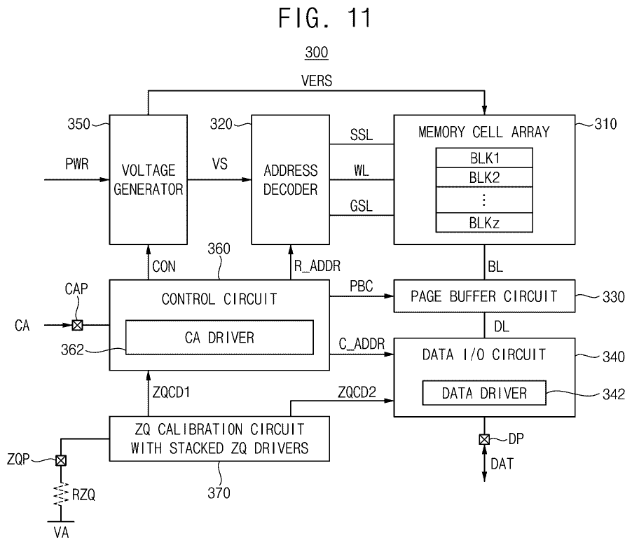

In some example embodiments, the ZQ calibration circuit 100 may be included in a memory device, and may control impedance matching of signal pads included in the memory device. An example of the memory device including the ZQ calibration circuit 100 will be described with reference to FIGS. 10 and 11.

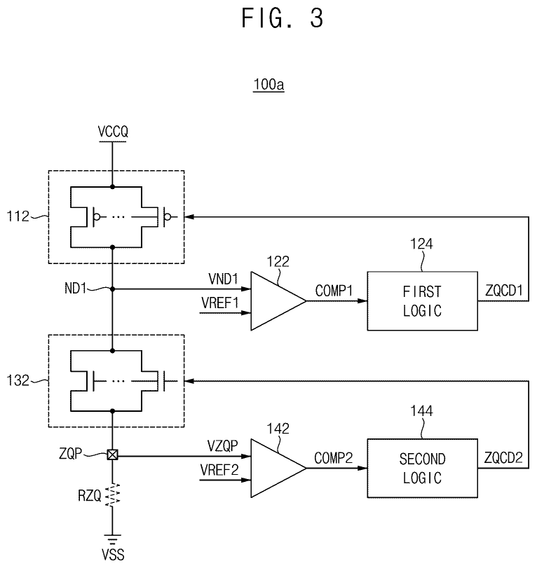

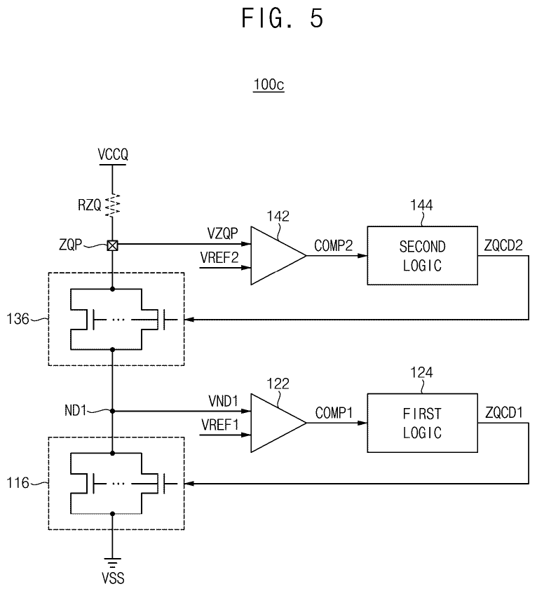

The first ZQ driver 110 is connected between a first voltage V1 and a first node ND1, and an impedance of the first ZQ driver 110 is adjusted based on a first calibration code ZQCD1. For example, the first voltage V1 may be one of a first power supply voltage (e.g., a first power supply voltage VCCQ in FIG. 3) and a ground voltage (e.g., a ground voltage VSS in FIG. 5). For example, the first ZQ driver 110 may include a plurality of first transistors.

The second ZQ driver 130 is connected between the first node ND1 and a ZQ pad ZQP, and an impedance of the second ZQ driver 130 is adjusted based on a second calibration code ZQCD2. For example, the second ZQ driver 130 may include a plurality of second transistors.

In some example embodiments, the first ZQ driver 110 and the second ZQ driver 130 may operate based on different power supply voltages.

In some example embodiments, the plurality of first transistors included in the first ZQ driver 110 and the plurality of second transistors included in the second ZQ driver 130 may be transistors of the same type. In other example embodiments, the plurality of first transistors included in the first ZQ driver 110 and the plurality of second transistors included in the second ZQ driver 130 may be transistors of different types.

The first ZQ driver 110 and the second ZQ driver 130 may be disposed or arranged in a stacked manner on (or under) the ZQ pad ZQP. In other words, the first ZQ driver 110 and the second ZQ driver 130 may be connected in series between the first voltage V1 and the ZQ pad ZQP. The ZQ calibration circuit 100 according to example embodiments may include two ZQ drivers that are disposed in the stacked manner, and such structure may be referred to as a stacked ZQ driver structure.

In some example embodiments, the ZQ pad ZQP may be disposed or arranged inside or outside the ZQ calibration circuit 100. The ZQ pad ZQP may be connected to a ZQ resistor RZQ that is located outside the ZQ calibration circuit 100, and the ZQ resistor RZQ may be connected between the ZQ pad ZQP and a second voltage V2. For example, the second voltage V2 may be different from the first voltage V1, and may be the other of the first power supply voltage (e.g., the first power supply voltage VCCQ in FIG. 3) and the ground voltage (e.g., the ground voltage VSS in FIG. 5). Therefore, the first ZQ driver 110, the second ZQ driver 130 and the ZQ resistor RZQ may be connected in series between the first voltage V1 and the second voltage V2.

Examples of the first ZQ driver 110 and examples of the second ZQ driver 130 will be described with reference to FIGS. 3, 4 and 5.

The first ZQ calibrator 120 is connected to the first node ND1, receives a first reference voltage VREF1, and generates the first calibration code ZQCD1 by performing a first calibration operation based on a voltage at the first node ND1 and the first reference voltage VREF1.

The second ZQ calibrator 140 is connected to the ZQ pad ZQP, receives a second reference voltage VREF2 different from the first reference voltage VREF1, and generates the second calibration code ZQCD2 by performing a second calibration operation based on a voltage at the ZQ pad ZQP and the second reference voltage VREF2.

An example of the first ZQ calibrator 120 and an example of the second ZQ calibrator 140 will be described with reference to FIG. 3.

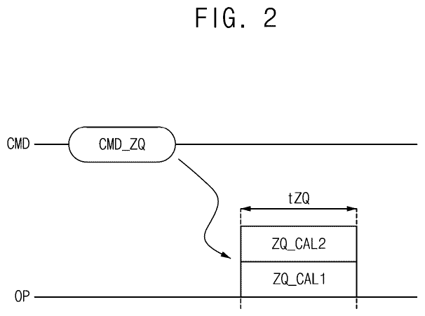

FIG. 2 is a diagram for describing an operation of a ZQ calibration circuit of FIG. 1.

Referring to FIGS. 1 and 2, a first calibration operation ZQ_CAL1 using the first ZQ driver 110 and the first ZQ calibrator 120 and a second calibration operation ZQ_CAL2 using the second ZQ driver 130 and the second ZQ calibrator 140 may be substantially simultaneously or concurrently performed.

For example, the memory device including the ZQ calibration circuit 100 may receive a command CMD from a memory controller (e.g., a memory controller 20 in FIG. 10) located outside the memory device, and may perform various operations OP based on the command CMD. For example, the memory device may receive a ZQ command CMD_ZQ from the memory controller, and the ZQ calibration circuit 100 may perform a ZQ calibration operation for controlling impedance matching based on the ZQ command CMD_ZQ.

For example, during one ZQ interval (or period) tZQ based on one ZQ command CMD_ZQ, the ZQ calibration circuit 100 may substantially simultaneously perform the first calibration operation ZQ_CAL1 and the second calibration operation ZQ_CAL2. In other words, during one ZQ interval tZQ, the first calibration operation ZQ_CAL1 and the second calibration operation ZQ_CAL2 may be substantially simultaneously started and may be substantially simultaneously completed, rather than the first calibration operation ZQ_CAL1 is started first and the second calibration operation ZQ_CAL2 is started after the first calibration operation ZQ_CAL1 is completed.

In some example embodiments, to substantially simultaneously perform the first calibration operation ZQ_CAL1 and the second calibration operation ZQ_CAL2, the ZQ calibration circuit 100 may include not only two ZQ drivers 110 and 130 but also two ZQ calibrators 120 and 140. In other words, the number of ZQ drivers 110 and 130 included in the ZQ calibration circuit 100 and the number of ZQ calibrators 120 and 140 included in the ZQ calibration circuit 100 may be equal to each other.

In some example embodiments, an operation that the first calibration operation ZQ_CAL1 and the second calibration operation ZQ_CAL2 are substantially simultaneously performed may represent or indicate that at least a portion of an interval during which the first calibration operation ZQ_CAL1 is performed and at least a portion of an interval during which the second calibration operation ZQ_CAL2 is performed overlap during one ZQ interval tZQ. In other words, it may not represent that the first calibration operation ZQ_CAL1 and the second calibration operation ZQ_CAL2 are always performed simultaneously throughout one ZQ interval tZQ. However, example embodiments are not limited thereto, and the operation that the first calibration operation ZQ_CAL1 and the second calibration operation ZQ_CAL2 are substantially simultaneously performed may also represent that the interval during which the first calibration operation ZQ_CAL1 is performed and the interval during which the second calibration operation ZQ_CAL2 is performed entirely overlap during one ZQ interval tZQ.

Hereinafter, the ZQ calibration operation supported by the ZQ calibration circuit 100 will be described.

Memory devices may output a signal to a channel and may receive a signal transmitted from the channel, via an input/output (I/O) pad. At least a portion of the signals, which are transmitted and received via the channel, may be reflected at a receiving end (hereinafter referred to as a reflected signal), and such a reflected signal may affect as noise of an original signal. Thus, signal integrity may be deteriorated. A swing width of a signal may be reduced to significantly reduce transmission time of a signal transmitted and received between memory devices. However, in general the smaller the swing width, the more vulnerability to the noise.

In addition, an influence of the reflected signal may be increased with the presence of impedance mismatching between the transmitting end and the receiving end. The impedance mismatching may occur due to one or more variations in one or more of a process, a voltage and a temperature (PVT).

A termination resistance may be employed to remove or help remove such a reflected signal and to improve signal integrity. The termination resistance may match impedance between the transmitting end and the receiving end of the memory device. For example, in a memory device with a significantly high operating speed, on-die-termination (ODT) technology, in which a termination resistance is employed on a die of a memory device, may be applied to block a reflected signal and signal interference between memory devices.

A ZQ calibration operation may represent or indicate a process of correcting such termination resistance to appropriately or more successfully perform impedance matching. In the ZQ calibration operation, calibration codes that vary depending on PVT may be generated, and termination resistance may be adjusted based on the generated calibration codes to perform impedance matching between memory devices transmitting and receiving signals.

In some example embodiments, the ZQ calibration operation may include an initial ZQ calibration operation (hereinafter referred to as a ZQ long calibration operation) and a runtime ZQ calibration operation (hereinafter referred to as a ZQ short calibration operation). The ZQ long calibration operation may be performed for a relatively long time (e.g., for one us or less) in an initial operation time of the memory device, and the ZQ short calibration operation may be performed for a relatively short time, which may be shorter than the ZQ long calibration time (e.g. for about 0.3 us or less), while the memory device is operating.

The ZQ calibration circuit 100 according to example embodiments may include the first ZQ driver 110 and the second ZQ driver 130 that operate based on different power supply voltages and are implemented with the stacked structure. In addition, the ZQ calibration circuit 100 may include the first ZQ calibrator 120 and the second ZQ calibrator 140 for controlling the first ZQ driver 110 and the second ZQ driver 130, respectively. In the ZQ calibration circuit 100, the first calibration operation ZQ_CAL1 and the second calibration operation ZQ_CAL2 may be substantially simultaneously performed using two ZQ drivers 110 and 130 and two ZQ calibrators 120 and 140. Accordingly, two ZQ calibration operations ZQ_CAL1 and ZQ_CAL2 may be performed rapidly and efficiently without increasing the execution time.

FIGS. 3, 4 and 5 are diagrams illustrating examples of a ZQ calibration circuit of FIG. 1.

Referring to FIG. 3, a ZQ calibration circuit 100a may include a plurality of first transistors 112, a first comparator 122, a first logic (or circuit) 124, a plurality of second transistors 132, a second comparator 142 and a second logic 144.

FIG. 3 illustrates an example where the first voltage V1 is a first power supply voltage VCCQ and the second voltage V2 is a ground voltage VSS in the ZQ calibration circuit 100 of FIG. 1, and illustrates an example where the first ZQ driver 110 and the second ZQ driver 130 in FIG. 1 include transistors of different types. The descriptions repeated with or overlapping with descriptions of FIG. 1 will be omitted in the interest of brevity.

The plurality of first transistors 112 may be included in the first ZQ driver 110 of FIG. 1. The plurality of first transistors 112 may be connected in parallel between the first power supply voltage VCCQ (or a terminal receiving the first power supply voltage VCCQ) and the first node ND1, and may be turned on and off based on the first calibration code ZQCD1. For example, the plurality of first transistors 112 may be p-type metal oxide semiconductor (PMOS) transistors.

In some example embodiments, the first calibration code ZQCD1 may include a plurality of first bits (or a plurality of first control signals corresponding to the plurality of first bits), and each of the plurality of first bits may be applied to a gate electrode of a respective one of the plurality of first transistors 112 for controlling on and off of each first transistor. For example, the impedance of the first ZQ driver 110 may be adjusted or controlled based on the number of first transistors turned on and the number of first transistors turned off among the plurality of first transistors 112.

In some example embodiments, the first ZQ driver 110 including the plurality of first transistors 112 may operate based on the first power supply voltage VCCQ. For example, as will be described with reference to FIG. 11, when the ZQ calibration circuit 100a is included in a memory device, the memory device may further include a first driver having a configuration the same as that of the first ZQ driver 110. The first ZQ driver 110 may be configured and used for impedance matching of the first driver, and the first driver and the first ZQ driver 110 may be referred to as a main circuit and a replica circuit, respectively. The first driver and the first ZQ driver 110 may operate based on the same power supply voltage (e.g., the first power supply voltage VCCQ).

The first comparator 122 and the first logic 124 may be included in the first ZQ calibrator 120 of FIG. 1. The first comparator 122 may generate a first comparison signal COMP1 by comparing a voltage VND1 at the first node ND1 with the first reference voltage VREF1. The first logic 124 may generate the first calibration code ZQCD1 based on the first comparison signal COMP1.

In some example embodiments, the first calibration code ZQCD1 may be generated (e.g., a value of the first calibration code ZQCD1 may be determined) such that a voltage level of the voltage VND1 at the first node ND1 and a voltage level of the first reference voltage VREF1 become substantially equal to each other. In other words, the first calibration operation ZQ_CAL1 in FIG. 2 may represent an operation of adjusting the impedance of the first ZQ driver 110 so that the voltage level of the voltage VND1 at the first node ND1 and the voltage level of the first reference voltage VREF1 become substantially equal to each other.

The plurality of second transistors 132 may be included in the second ZQ driver 130 of FIG. 1. The plurality of second transistors 132 may be connected in parallel between the first node ND1 and the ZQ pad ZQP, and may be turned on and off based on the second calibration code ZQCD2. For example, the plurality of second transistors 132 may be n-type metal oxide semiconductor (NMOS) transistors.

In some example embodiments, the second calibration code ZQCD2 may include a plurality of second bits (or a plurality of second control signals corresponding to the plurality of second bits), and each of the plurality of second bits may be applied to a gate electrode of a respective one of the plurality of second transistors 132 for controlling on and off of each second transistor. For example, the impedance of the second ZQ driver 130 may be adjusted based on the number of second transistors turned on and the number of second transistors turned off among the plurality of second transistors 132.

In some example embodiments, the second ZQ driver 130 including the plurality of second transistors 132 may operate based on a second power supply voltage (e.g., VCCQL) having a voltage level lower than that of the first power supply voltage VCCQ. For example, the second power supply voltage may have a voltage level equal to that of the first reference voltage VREF1. For example, as will be described with reference to FIG. 11, when the ZQ calibration circuit 100a is included in the memory device, the memory device may further include a second driver having a configuration the same as that of the second ZQ driver 130. The second ZQ driver 130 may be configured and used for impedance matching of the second driver, and the second driver and the second ZQ driver 130 may be referred to as a main circuit and a replica circuit, respectively. The second driver and the second ZQ driver 130 may operate based on the same power supply voltage (e.g., the second power supply voltage), and may operate based on a power supply voltage different from the first driver and the first ZQ driver 110.

The second comparator 142 and the second logic 144 may be included in the second ZQ calibrator 140 of FIG. 1. The second comparator 142 may generate a second comparison signal COMP2 by comparing a voltage VZQP at the ZQ pad ZQP with the second reference voltage VREF2. The second logic 144 may generate the second calibration code ZQCD2 based on the second comparison signal COMP2. In other words, the second comparator 142 and the second logic 144 may have configurations and operations similar to those of the first comparator 122 and the first logic 124, respectively.

In some example embodiments, the second calibration code ZQCD2 may be generated such that the voltage level of the voltage VZQP at the ZQ pad ZQP and the voltage level of the second reference voltage VREF2 become substantially equal to each other. In other words, the second calibration operation ZQ_CAL2 in FIG. 2 may represent an operation of adjusting the impedance of the second ZQ driver 130 so that the voltage level of the voltage VZQP at the ZQ pad ZQP and the voltage level of the second reference voltage VREF2 become substantially equal to each other.

In the example of FIG. 3, the voltage level of the first reference voltage VREF1 may be lower than the voltage level of the first power supply voltage VCCQ, and the voltage level of the second reference voltage VREF2 may be lower than the voltage level of the first reference voltage VREF1. For example, the voltage level of the first power supply voltage VCCQ may be about 1.2V, the voltage level of the first reference voltage VREF1 may be about 0.6V, and the voltage level of the second reference voltage VREF2 may be about 0.3V. However, example embodiments are not limited thereto.

In some example embodiments, when the first calibration operation ZQ_CAL1 and the second calibration operation ZQ_CAL2 are successfully completed, e.g., when the voltage level of the voltage VND1 at the first node ND1 and the voltage level of the first reference voltage VREF1 become substantially equal to each other and the voltage level of the voltage VZQP at the ZQ pad ZQP and the voltage level of the second reference voltage VREF2 become substantially equal to each other, a second resistance (or impedance) of the second ZQ driver 130 may be substantially equal to a resistance of the ZQ resistor RZQ, and a first resistance (or impedance) of the first ZQ driver 110 may be substantially equal to the sum of the second resistance and the resistance of the ZQ resistor RZQ. For example, when the resistance of the ZQ resistor RZQ is about 300 Ω, and when the first calibration operation ZQ_CAL1 and the second calibration operation ZQ_CAL2 are successfully completed, the second resistance may be set to about 300 Ω, and the first resistance may be set to about 600 Ω. However, example embodiments are not limited thereto.

In the example of FIG. 3, the ZQ resistor RZQ may be connected between the ZQ pad ZQP and the ground voltage VSS (or a terminal receiving the ground voltage VSS).

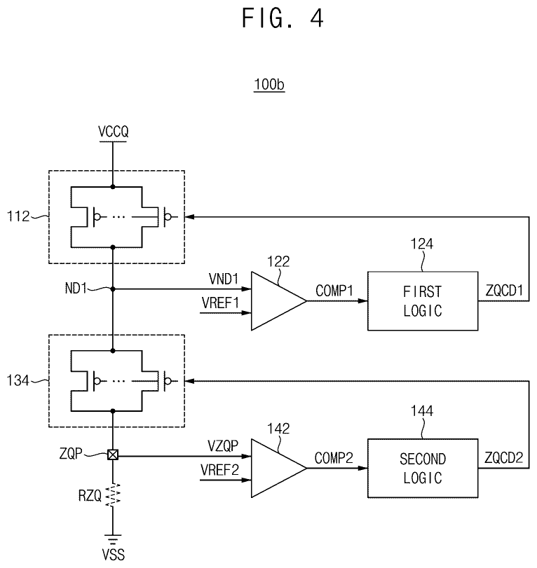

Referring to FIG. 4, a ZQ calibration circuit 100b may include a plurality of first transistors 112, a first comparator 122, a first logic 124, a plurality of second transistors 134, a second comparator 142 and a second logic 144.

The ZQ calibration circuit 100b of FIG. 4 may be substantially the same as the ZQ calibration circuit 100a of FIG. 3, except that a configuration of the plurality of second transistors 134 is changed. The descriptions repeated with or overlapping with descriptions of FIGS. 1 and 3 will be omitted in the interest of brevity.

The plurality of second transistors 134 may be included in the second ZQ driver 130 of FIG. 1. The plurality of second transistors 134 may be connected in parallel between the first node ND1 and the ZQ pad ZQP, and may be turned on and off based on the second calibration code ZQCD2. For example, the plurality of second transistors 134 may be PMOS transistors.

Referring to FIG. 5, a ZQ calibration circuit 100c may include a plurality of first transistors 116, a first comparator 122, a first logic 124, a plurality of second transistors 136, a second comparator 142 and a second logic 144.

FIG. 5 illustrates an example where the first voltage V1 is the ground voltage VSS and the second voltage V2 is the first power supply voltage VCCQ in the ZQ calibration circuit 100 of FIG. 1, and illustrates an example where the first ZQ driver 110 and the second ZQ driver 130 of FIG. 1 include transistors of the same type. The descriptions repeated with or overlapping with descriptions of FIGS. 1 and 3 will be omitted in the interest of brevity.

The plurality of first transistors 116 may be included in the first ZQ driver 110 of FIG. 1. The plurality of first transistors 116 may be connected in parallel between the ground voltage VSS (or a terminal receiving the ground voltage VSS) and the first node ND1, and may be turned on and off based on the first calibration code ZQCD1. For example, the plurality of first transistors 116 may be NMOS transistors. An operation of the plurality of first transistors 116 may be substantially the same as the operation of the plurality of first transistors 112 described with reference to FIG. 3.

In some example embodiments, the first ZQ driver 110 including the plurality of first transistors 116 may operate based on a power supply voltage having a voltage level equal to that of the first reference voltage VREF1.

The plurality of second transistors 136 may be included in the second ZQ driver 130 of FIG. 1. The plurality of second transistors 136 may be connected in parallel between the first node ND1 and the ZQ pad ZQP, and may be turned on and off based on the second calibration code ZQCD2. For example, the plurality of second transistors 136 may be NMOS transistors. An operation of the plurality of second transistors 136 may be substantially the same as the operation of the plurality of second transistors 132 described with reference to FIG. 3.

In some example embodiments, the second ZQ driver 130 including the plurality of second transistors 136 may operate based on a power supply voltage having a voltage level equal to that of the second reference voltage VREF2.

As described above, the first ZQ driver 110 and the second ZQ driver 130 may operate based on power supply voltages having different voltage levels.

Configurations and operations of the first comparator 122, the first logic 124, the second comparator 142 and the second logic 144 may be substantially the same as those described with reference to FIG. 3.

In the example of FIG. 5, the voltage level of the second reference voltage VREF2 may be lower than the voltage level of the first power supply voltage VCCQ, and the voltage level of the first reference voltage VREF1 may be lower than the voltage level of the second reference voltage VREF2.

In the example of FIG. 5, the ZQ resistor RZQ may be connected between the ZQ pad ZQP and the first power supply voltage VCCQ (or a terminal receiving the first power supply voltage VCCQ).

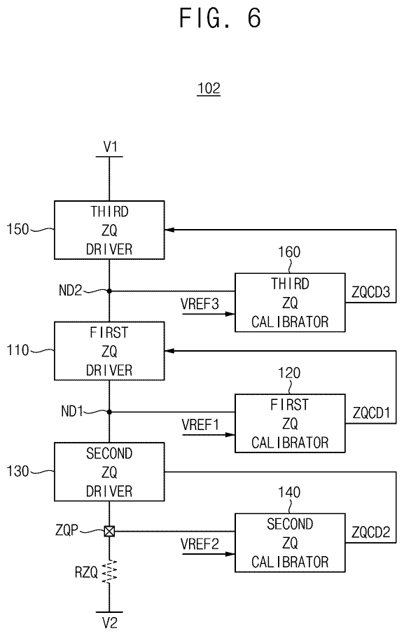

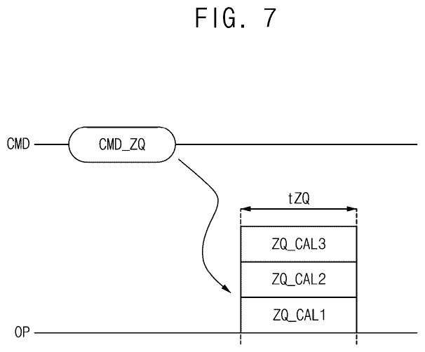

FIG. 6 is a block diagram illustrating a ZQ calibration circuit according to example embodiments. FIG. 7 is a diagram for describing an operation of a ZQ calibration circuit of FIG. 6. The descriptions repeated with or overlapping with descriptions of FIGS. 1 and 2 will be omitted in the interest of brevity.

Referring to FIG. 6, a ZQ calibration circuit 102 includes a first ZQ driver 110, a first ZQ calibrator 120, a second ZQ driver 130 and a second ZQ calibrator 140. The ZQ calibration circuit 102 may further include a third ZQ driver 150 and a third ZQ calibrator 160.

The ZQ calibration circuit 102 of FIG. 6 may be substantially the same as the ZQ calibration circuit 100 of FIG. 1, except that the ZQ calibration circuit 102 further includes the third ZQ driver 150 and the third ZQ calibrator 160.

The third ZQ driver 150 may be connected between the first voltage V1 and the first ZQ driver 110, and an impedance of the third ZQ driver 150 may be adjusted based on a third calibration code ZQCD3. For example, the third ZQ driver 150 may include a plurality of third transistors.

The first ZQ driver 110, the second ZQ driver 130 and the third ZQ driver 150 may be disposed in a stacked manner on (or under) the ZQ pad ZQP. The ZQ calibration circuit 102 according to example embodiments may include three ZQ drivers that are disposed in the stacked manner. The first ZQ driver 110, the second ZQ driver 130 and the third ZQ driver 150 may operate based on different power supply voltages.

In some example embodiments, the types of transistors included in the first ZQ driver 110, the second ZQ driver 130 and the third ZQ driver 150 may be the same as or different from each other. For example, when the first voltage V1 is the first power supply voltage VCCQ and the second voltage V2 is the ground voltage VSS as described with reference to FIGS. 3 and 4, the third transistors included in the third ZQ driver 150 that is directly connected to the first power supply voltage VCCQ may be PMOS transistors, and the first and second transistors included in the first and second ZQ drivers 110 and 130 that are connected under the third ZQ driver 150 may be NMOS transistors or PMOS transistors. For example, when the first voltage V1 is the ground voltage VSS and the second voltage V2 is the first power supply voltage VCCQ as described with reference to FIG. 5, all of the first, second and third transistors included in the first, second and third ZQ drivers 110, 130 and 150 may be NMOS transistors.

The third ZQ calibrator 160 may be connected to a second node ND2 between the first ZQ driver 110 and the third ZQ driver 150, may receive a third reference voltage VREF3 different from the first reference voltage VREF1 and the second reference voltage VREF2, and may generate the third calibration code ZQCD3 by performing a third calibration operation based on a voltage at the second node ND2 and the third reference voltage VREF3. For example, the third ZQ calibrator 160 may have a configuration and operation substantially the same as those of the first ZQ calibrator 120 and the second ZQ calibrator 140.

Referring to FIGS. 6 and 7, a first calibration operation ZQ_CAL1 using the first ZQ driver 110 and the first ZQ calibrator 120, a second calibration operation ZQ_CAL2 using the second ZQ driver 130 and the second ZQ calibrator 140, and a third calibration operation ZQ_CAL3 using the third ZQ driver 150 and the third ZQ calibrator 160 may be substantially simultaneously performed.

For example, during one ZQ interval tZQ based on one ZQ command CMD_ZQ, the ZQ calibration circuit 102 may substantially simultaneously perform the first calibration operation ZQ_CAL1, the second calibration operation ZQ_CAL2 and the third calibration operation ZQ_CAL3.

In some example embodiments, to substantially simultaneously perform the first calibration operation ZQ_CAL1, the second calibration operation ZQ_CAL2 and the third calibration operation ZQ_CAL3, the ZQ calibration circuit 100 may include not only three ZQ drivers 110, 130 and 150 but also three ZQ calibrators 120, 140 and 160.

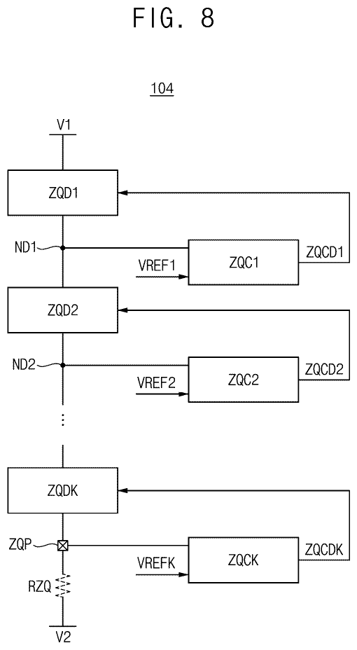

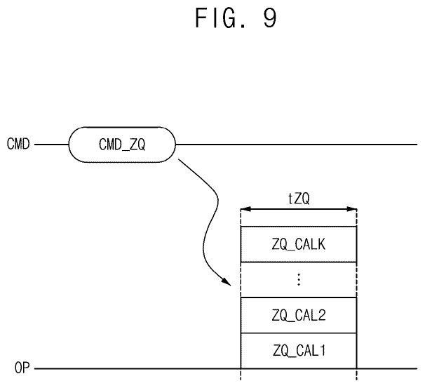

FIG. 8 is a block diagram illustrating a ZQ calibration circuit according to example embodiments. FIG. 9 is a diagram for describing an operation of a ZQ calibration circuit of FIG. 9. The descriptions repeated with or overlapping with descriptions of FIGS. 1 and 2 will be omitted in the interest of brevity.

Referring to FIG. 8, a ZQ calibration circuit 104 may include first to K-th ZQ drivers ZQD1, ZQD2, . . . , ZQDK and first to K-th ZQ calibrators ZQC1, ZQC2, . . . , ZQCK, where K is a positive integer greater than or equal to three.

The first to K-th ZQ drivers ZQD1, ZQD2, . . . , ZQDK may be disposed in a stacked manner on (or under) the ZQ pad ZQP, and may be connected in series between the first voltage V1 and the ZQ pad ZQP. The ZQ calibration circuit 104 according to example embodiments may include K ZQ drivers that are disposed in the stacked manner. The first to K-th ZQ drivers ZQD1, ZQD2, . . . , ZQDK may operate based on different power supply voltages.

In some example embodiments, as described with reference to FIGS. 3, 4, 5 and 6, each of the first to K-th ZQ drivers ZQD1, ZQD2, . . . , ZQDK may include a plurality of transistors, and the types of transistors included in the first to K-th ZQ drivers ZQD1, ZQD2, . . . , ZQDK may be the same as or different from each other.

The first ZQ calibrator ZQC1 may be connected to a first node ND1 under the first ZQ driver ZQD1 (e.g.,, between the first and second ZQ drivers ZQD1 and ZQD2), may receive a first reference voltage VREF1, and may generate a first calibration code ZQCD1 by performing a first calibration operation based on a voltage at the first node ND1 and the first reference voltage VREF1.

The second ZQ calibrator ZQC2 may be connected to a second node ND2 under the second ZQ driver ZQD2, may receive a second reference voltage VREF2, and may generate a second calibration code ZQCD2 by performing a second calibration operation based on a voltage at the second node ND2 and the second reference voltage VREF2.

The K-th ZQ calibrator ZQCK may be connected to the ZQ pad ZQP, may receive a K-th reference voltage VREFK, and may generate a K-th calibration code ZQCDK by performing a K-th calibration operation based on a voltage at the ZQ pad ZQP and the K-th reference voltage VREFK.

The first to K-th ZQ calibrators ZQC1, ZQC2, . . . , ZQCK may have substantially the same configurations and operations.

Referring to FIGS. 8 and 9, first to K-th calibration operations ZQ_CAL1, ZQ_CAL2, . . . , ZQ_CALK may be substantially simultaneously performed.

For example, during one ZQ interval tZQ based on one ZQ command CMD_ZQ, the ZQ calibration circuit 104 may substantially simultaneously perform the first to K-th calibration operations ZQ_CAL1, ZQ_CAL2, . . . , ZQ_CALK.

In some example embodiments, to substantially simultaneously perform the first to K-th calibration operations ZQ_CAL1, ZQ_CAL2, . . . , ZQ_CALK, the ZQ calibration circuit 100 may include not only K ZQ drivers ZQD1, ZQD2, . . . , ZQDK but Also K ZQ calibrators ZQC1, ZQC2, . . . , ZQCK.

The ZQ calibration circuits 102 and 104 according to example embodiments may include the plurality of ZQ drivers that operate based on different power supply voltages and are implemented with the stacked structure, may include the plurality of ZQ calibrators for controlling the plurality of ZQ drivers, and may substantially simultaneously perform the plurality of calibration operations using the plurality of ZQ drivers and the plurality of ZQ calibrators. Accordingly, the plurality of ZQ calibration operations may be performed rapidly and efficiently without increasing the execution time.

Although the ZQ calibration circuit according to example embodiments is described based on a specific number of ZQ drivers, a specific number of ZQ calibrators, a structure of the ZQ driver including specific types of transistors, and a structure of the ZQ calibrator including specific components, example embodiments are not limited thereto.

FIG. 10 is a block diagram illustrating a memory system including the memory device according to example embodiments.

Referring to FIG. 10, a memory system 10 includes a memory controller 20 and a memory device 40. The memory system 10 may further include a plurality of signal lines 30 that electrically connect the memory controller 20 with the memory device 40.

The memory device 40 is controlled by the memory controller 20. For example, based on requests from a host device (not illustrated), the memory controller 20 may store (e.g., write or program) data into the memory device 40, or may retrieve (e.g., read or sense) data from the memory device 40.

The plurality of signal lines 30 may include control lines, command/address lines, data input/output (I/O) lines and power lines. The memory controller 20 may transmit a command/address CA and a control signal CTRL to the memory device 40 via the command/address lines and the control lines, may exchange data DAT with the memory device 40 via the data I/O lines, and may transmit a power supply voltage PWR to the memory device 40 via the power lines. For example, the command/address CA may include a command and an address. Although not illustrated in detail, the plurality of signal lines 30 may further include data strobe signal (DQS) lines for transmitting a DQS signal.

The memory device 40 includes a memory cell array 42, a ZQ calibration circuit 44, a first pad P1 and a second pad P2.

The memory cell array 42 stores the data DAT. The first pad P1 and the second pad P2 input and output a first signal and a second signal, which are used for operating the memory cell array 42, respectively. For example, the first signal may be the command/address CA, and the second signal may be the data DAT, but example embodiments are not limited thereto. For example, the first signal and the second signal may be implemented based on different interfaces.

The ZQ calibration circuit 44 performs a ZQ calibration operation on the first pad P1 and the second pad P2. The ZQ calibration circuit 44 may be the ZQ calibration circuit according to example embodiments, and may be implemented with the stacked ZQ driver structure. For example, the ZQ calibration circuit 44 may include two ZQ drivers that operate based on different power supply voltages and are implemented with the stacked structure, may include two ZQ calibrators for controlling two ZQ drivers, and may substantially simultaneously perform two calibration operations using two ZQ drivers and two ZQ calibrators. Accordingly, two ZQ calibration operations may be performed rapidly and efficiently without increasing the execution time.

The ZQ calibration circuit 44 may be connected to a ZQ pad ZQP, and may be connected to a ZQ resistor RZQ located outside the memory device 40 via the ZQ pad ZQP. For example, the ZQ pad ZQP may be disposed inside or outside the memory device 40. For example, the ZQ resistor RZQ may be connected between the ZQ pad ZQP and a voltage VA. For example, as described with reference to FIGS. 3, 4 and 5, the voltage VA may be a power supply voltage or a ground voltage.

In some example embodiments, as will be described with reference to FIG. 11, the memory device 40 may further include a first driver connected to the first pad P1 and for driving the first signal, and a second driver connected to the second pad P2 and for driving the second signal.

FIG. 11 is a block diagram illustrating a memory device according to example embodiments.

Referring to FIG. 11, a memory device 300 may include a memory cell array 310, an address decoder 320, a page buffer circuit 330, a data input/output (I/O) circuit 340, a voltage generator 350, a control circuit 360 and a ZQ calibration circuit 370. For example, the memory device 300 may be one of various nonvolatile memories such as a NAND flash memory.

The memory cell array 310 may be connected to the address decoder 320 via a plurality of string selection lines SSL, a plurality of wordlines WL and a plurality of ground selection lines GSL. The memory cell array 310 may be further connected to the page buffer circuit 330 via a plurality of bitlines BL. The memory cell array 310 may include a plurality of memory cells (e.g., a plurality of nonvolatile memory cells) that are connected to the plurality of wordlines WL and the plurality of bitlines BL. The memory cell array 310 may be divided into a plurality of memory blocks BLK1, BLK2, . . . , BLKz each of which includes memory cells.

In some example embodiments, the plurality of memory cells may be arranged in a two-dimensional (2D) array structure or a three-dimensional (3D) vertical array structure. A three-dimensional vertical array structure may include vertical cell strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

The control circuit 360 may receive a command/address CA from a memory controller (e.g., the memory controller 20 in FIG. 10) located outside the memory device 300, and may control erasure, programming and read operations of the memory device 300 based on the command/address CA. An erase operation may include performing a sequence of erase loops, and a programming operation may include performing a sequence of program loops. Each program loop may include a program operation and a program verification operation. Each erase loop may include an erase operation and an erase verification operation. The read operation may include a normal read operation and data recovery read operation.

For example, the control circuit 360 may generate control signals CON, which are used for controlling the voltage generator 350, and may generate control signal PBC for controlling the page buffer circuit 330, based on the command/address CA, and may generate a row address R_ADDR and a column address C_ADDR based on the command/address CA. The control circuit 360 may provide the row address R_ADDR to the address decoder 320 and may provide the column address C_ADDR to the data I/O circuit 340.

The address decoder 320 may be connected to the memory cell array 310 via the plurality of string selection lines SSL, the plurality of wordlines WL and the plurality of ground selection lines GSL. For example, in the data erase/write/read operations, the address decoder 320 may determine at least one of the plurality of wordlines WL as a selected wordline, at least one of the plurality of string selection lines SSL as a selected string selection line, and at least one of the plurality of ground selection lines GSL as a selected ground selection line, based on the row address R_ADDR.

The voltage generator 350 may generate voltages VS that are required for an operation of the memory device 300 based on a power PWR and the control signals CON. The voltages VS may be applied to the plurality of string selection lines SSL, the plurality of wordlines WL and the plurality of ground selection lines GSL via the address decoder 320. In addition, the voltage generator 350 may generate an erase voltage VERS that is required for the erase operation based on the power PWR and the control signals CON.

The page buffer circuit 330 may be connected to the memory cell array 310 via the plurality of bitlines BL. The page buffer circuit 330 may include a plurality of page buffers. The page buffer circuit 330 may store data DAT to be programmed into the memory cell array 310 or may read data DAT sensed from the memory cell array 310. In other words, the page buffer circuit 330 may operate as a write driver or a sensing amplifier according to an operation mode of the memory device 300.

The data I/O circuit 340 may be connected to the page buffer circuit 330 via data lines DL. The data I/O circuit 340 may provide the data DAT from the outside of the memory device 300 to the memory cell array 310 via the page buffer circuit 330 or may provide the data DAT from the memory cell array 310 to the outside of the memory device 300, based on the column address C_ADDR.

The control circuit 360 may include a command/address (CA) driver 362 that receives the command/address CA via a command/address pad CAP. The command/address pad CAP may correspond to the first pad P1 in FIG. 10, and the command/address CA may correspond to the first signal in FIG. 10. The command/address driver 362 may correspond to the first driver connected to the first pad P1 in FIG. 10.

The data I/O circuit 340 may include a data driver 342 that inputs and outputs the data DAT via a data pad DP. The data pad DP may correspond to the second pad P2 in FIG. 10, and the data DAT may correspond to the second signal in FIG. 10. The data driver 342 may correspond to the second driver connected to the second pad P2 in FIG. 10.

The ZQ calibration circuit 370 may be the ZQ calibration circuit according to example embodiments described with reference to FIGS. 1 through 5. For example, the ZQ calibration circuit 370 may include the first ZQ driver 110, the first ZQ calibrator 120, the second ZQ driver 130 and the second ZQ calibrator 140. The first calibration operation ZQ_CAL1 using the first ZQ driver 110 and the first ZQ calibrator 120 and the second calibration operation ZQ_CAL2 using the second ZQ driver 130 and the second ZQ calibrator 140 may be substantially simultaneously performed. Accordingly, two ZQ calibration operations may be performed rapidly and efficiently without increasing the execution time.

In some example embodiments, the command/address driver 362 corresponding to the first driver may have a configuration substantially the same that of the first ZQ driver 110. For example, the first ZQ driver 110 may be a replica circuit of the command/address driver 362. The ZQ calibration circuit 370 may provide the first calibration code ZQCD1, which is finally determined by performing the first calibration operation ZQ_CAL1, to the control circuit 360, and an impedance of the command/address driver 362 may be adjusted based on the first calibration code ZQCD1.

In some example embodiments, the data driver 342 corresponding to the second driver may have a configuration substantially the same that of the second ZQ driver 130. For example, the second ZQ driver 130 may be a replica circuit of the data driver 342. The ZQ calibration circuit 370 may provide the second calibration code ZQCD2, which is finally determined by performing the second calibration operation ZQ_CAL2, to the data I/O circuit 340, and an impedance of the data driver 342 may be adjusted based on the second calibration code ZQCD2.

In some example embodiments, as with the first ZQ driver 110 and the second ZQ driver 130, the command/address driver 362 and the data driver 342 may operate based on different power supply voltages.

In some example embodiments, the command/address CA corresponding to the first signal and the data DAT corresponding to the second signal may be implemented based on different interfaces. For example, the command/address CA may be implemented based on a first interface, and the data DAT may be implemented based on a second interface different from the first interface. The ZQ calibration circuit 370 according to example embodiments may substantially simultaneously perform a ZQ calibration operation on the command/address driver 362 and the data driver 342 that drive the command/address CA and data DAT, respectively, are implemented based on different interfaces, and operate based on different power supply voltages. Accordingly, two ZQ calibration operations may be performed rapidly and effectively without increasing the execution time.

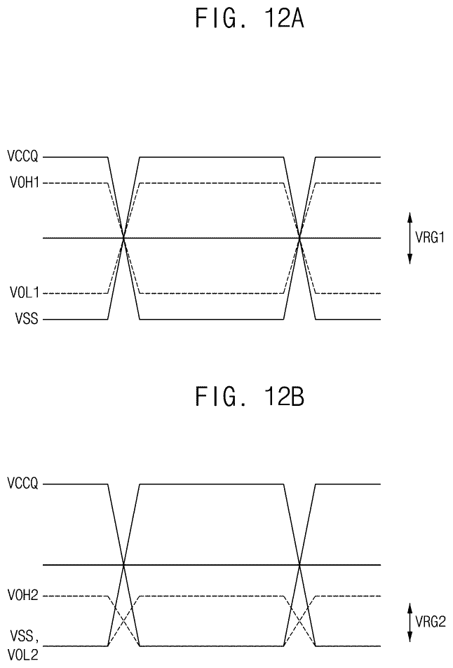

FIGS. 12A and 12B are diagrams for describing an operation of a memory device of FIG. 11.

Referring to FIG. 12A, an example of the first interface for the first signal (e.g., the command/address CA) is illustrated.

In some example embodiments, the first interface may be a center tapped termination (CTT) interface in which a common level of a swing of the first signal corresponds to a half of a voltage level of the first power supply voltage VCCQ. For example, in the CTT interface, an output signal of the CTT interface may have a signal swing of a half of the VCCQ level as a center (e.g., a common level). For example, VOH1 level corresponding to a logic high level of the output signal may be higher than a half of the VCCQ level, and VOL1 level corresponding to a logic low level of the output signal may be lower than a half of the VCCQ level.

Therefore, the CTT interface may have high resistance to VCCQ noise and to ground noise. The CTT interface may have an advantage of noise margin under, e.g., a heavy power load or a noise system. For example, a range VRG1 of a reference voltage for the CTT interface may be defined as a voltage within a predetermined range at a half of the VCCQ level.

Referring to FIG. 12B, an example of the second interface for the second signal (e.g., the data DAT) is illustrated.

In some example embodiments, the second interface may be a low tapped termination (LTT) interface in which a lowest level of a swing of the second signal corresponds to a voltage level of the ground voltage VSS. For example, the LTT interface may be a power isolated (PI)-LTT interface. For example, in the LTT interface, an output signal of the LTT interface may have a signal swing from the VSS level to VOH2 level corresponding to a logic high level of the output signal. For example, the VOH2 level corresponding to the logic high level of the output signal may be lower than a half of the VCCQ level, and VOL2 level corresponding to a logic low level of the output signal may be substantially equal to the VSS level.

In the LTT interface, a swing range may be automatically calibrated through a controller or a low-power operation. Since channel power is reduced to be equal to or lower than the VOH2 level (for example, the VOL2 level corresponding to the logic low level is grounded), the LTT interface may be appropriate to a light load system. For example, a range VRG2 of a reference voltage for the LTT interface operation may be defined as a voltage within a predetermined range between the ground voltage VSS and a half of the VOH2.

However, example embodiments are not limited thereto, and the first interface and the second interface may be implemented with various other interfaces.

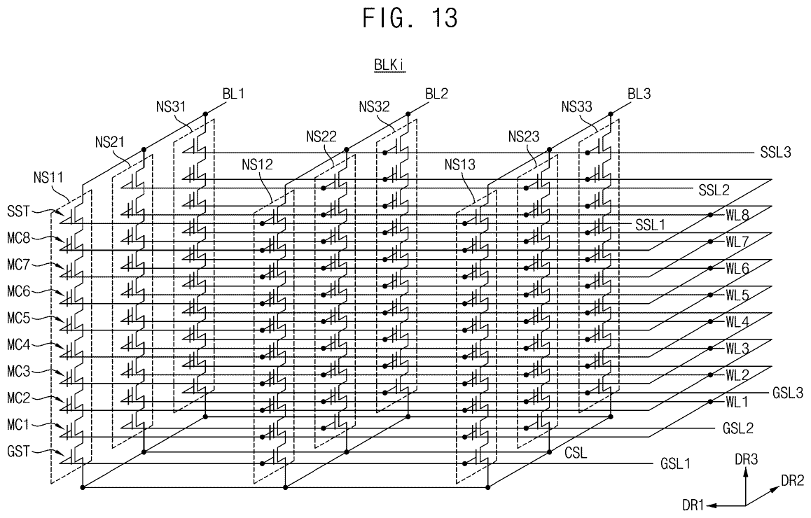

FIG. 13 is a circuit diagram illustrating an equivalent circuit of a memory block included in a memory device of FIG. 11.

A memory block BLKi of FIG. 13 may be formed on a substrate (e.g., a semiconductor substrate) in a three-dimensional structure (or a vertical structure). For example, a plurality of cell strings included in the memory block BLKi may be formed in a direction perpendicular to the substrate. For example, two directions substantially parallel to a first surface (e.g., a top surface) of the substrate and crossing each other are referred to as the first direction DR1 and the second direction DR2, and a direction substantially vertical to the first surface of the substrate is referred to as the third direction DR3. For example, the first and second directions DR1 and DR2 may be substantially perpendicular to each other. In addition, the third direction DR3 may be substantially perpendicular to both the first and second directions DR1 and DR2.

Referring to FIG. 13, the memory block BLKi may include a plurality of cell strings NS11, NS12, NS13, NS21, NS22, NS23, NS31, NS32 and NS33 connected between bitlines BL1, BL2 and BL3 and a common source line CSL. Each of the cell strings NS11, NS12, NS13, NS21, NS22, NS23, NS31, NS32 and NS33 may include a string selection transistor SST, a plurality of memory cells MC1, MC2, MC3, MC4, MC5, MC6, MC7 and MC8, and a ground selection transistor GST.

Each string selection transistor SST may be connected to a corresponding string selection line (one of SSL1, SSL2 and SSL3). The plurality of memory cells MC1, MC2, MC3, MC4, MC5, MC6, MC7 and MC8 may be connected to corresponding wordlines WL1, WL2, WL3, WL4, WL5, WL6, WL7 and WL8, respectively. Each ground selection transistor GST may be connected to a corresponding ground selection line (one of GSL1, GSL2 and GSL3). Each string selection transistor SST may be connected to a corresponding bitline (e.g., one of BL1, BL2 and BL3), and each ground selection transistor GST may be connected to the common source line CSL. In the example of FIG. 13, some of the string selection transistors SST are connected to the same bitline (e.g., one of BL1, BL2 and BL3) to connect corresponding cell strings to the same bitline via appropriate selection via selection voltages applied to the appropriate string selection lines SSL1 to SSL3 and ground selection lines GSL1, GSL2 and GSL3.

The cell strings connected in common to one bitline may form one column, and the cell strings connected to one string selection line may form one row. For example, the cell strings NS11, NS21 and NS31 connected to the first bitline BL1 may correspond to a first column, and the cell strings NS11, NS12 and NS13 connected to the first string selection line SSL1 may form a first row.

Wordlines (e.g., WL1) having the same height may be commonly connected, and the ground selection lines GSL1, GSL2 and GSL3 and the string selection lines SSL1, SSL2 and SSL3 may be separated. Memory cells located at the same semiconductor layer share a wordline. Cell strings in the same row share a string selection line. The common source line CSL is connected in common to all of the cell strings.

Although the memory device according to example embodiments is described based on a NAND flash memory device, the memory device according to example embodiments may be any volatile/nonvolatile memory device, e.g., a static random access memory (SRAM), a dynamic random access memory (DRAM), a phase-change random access memory (PRAM), a resistive random access memory (RRAM), a magnetic random access memory (MRAM), a ferroelectric random access memory (FRAM), etc.

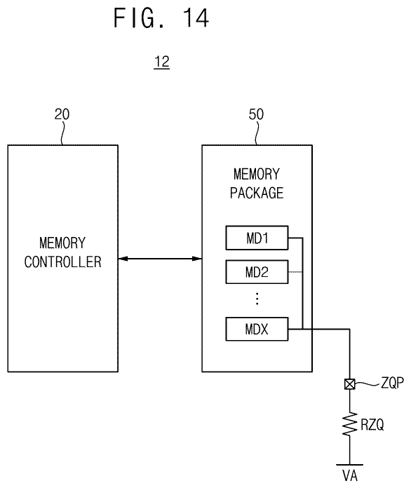

FIG. 14 is a block diagram illustrating a memory system according to example embodiments. The descriptions repeated with or overlapping with descriptions of FIG. 10 will be omitted in the interest of brevity.

Referring to FIG. 14, a memory system 12 includes a memory controller 20 and a memory package 50. The memory controller 20 may be substantially the same as that described with reference to FIG. 10.

The memory package 50 may include a plurality of memory devices MD1, MD2, . . . , MDX. Each of the plurality of memory devices MD1, MD2, . . . , MDX may be the memory device according to example embodiments, and may include a ZQ calibration circuit according to example embodiments. For example, the plurality of memory devices MD1, MD2, . . . , MDX may include first to X-th memory devices, where X is a positive integer greater than or equal to two.

In some example embodiments, ZQ calibration circuits included in the plurality of memory devices MD1, MD2, . . . , MDX may be commonly connected to the same ZQ pad ZQP and the same ZQ resistor RZQ.

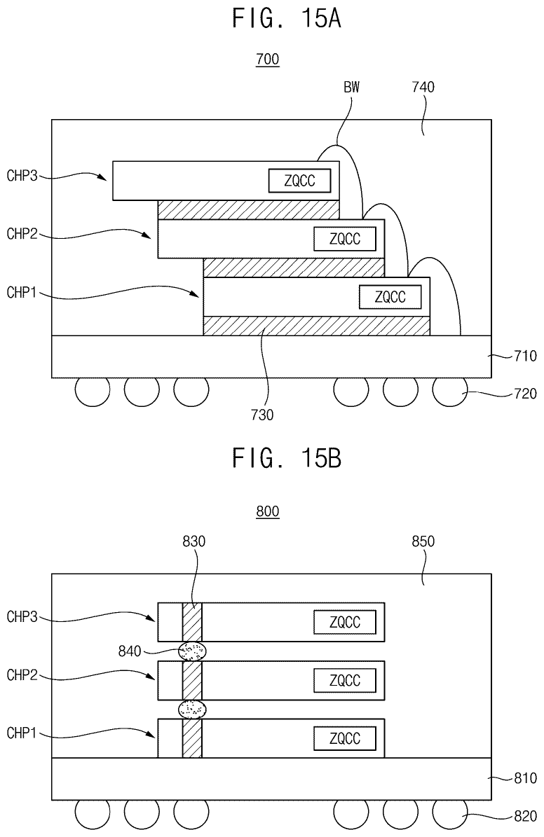

FIGS. 15A and 15B are diagrams illustrating examples of a memory package included in a memory system of FIG. 14.

Referring to FIG. 15A, a memory package 700 may include a base substrate 710, and a plurality of memory chips CHP1, CHP2 and CHP3 stacked on the base substrate 710.

Each of the memory chips CHP1, CHP2 and CHP3 may include the memory device according to example embodiments, and a ZQ calibration circuit ZQCC according to example embodiments.

In some example embodiments, the memory chips CHP1, CHP2 and CHP3 may be stacked on the base substrate 710 such that a surface on which I/O pads are formed faces upwards. In some example embodiments, with respect to each of the memory chips CHP1, CHP2 and CHP3, the I/O pads may be arranged near one side of the semiconductor substrate. As such, the memory chips CHP1, CHP2 and CHP3 may be stacked scalariformly, that is, in a step shape, such that the I/O pads of each memory chip may be exposed. In such stacked state, the memory chips CHP1, CHP2 and CHP3 may be electrically connected to the base substrate 710 through a plurality of bonding wires BW.

The stacked memory chips CHP1, CHP2 and CHP3 and the plurality of bonding wires BW may be fixed by a sealing member 740, and adhesive members 730 may intervene between the base substrate 710 and the memory chips CHP1, CHP2 and CHP3. Conductive bumps 720 may be formed on a bottom surface of the base substrate 710 for electrical connections to an external device.

Referring to FIG. 15B, a memory package 800 may include a base substrate 810, and a plurality of memory chips CHP1, CHP2 and CHP3 stacked on the base substrate 810. The descriptions repeated with or overlapping with descriptions of FIG. 15A will be omitted in the interest of brevity.

Each of the memory chips CHP1, CHP2 and CHP3 may further include a plurality of through silicon vias (TSVs) 830. Conductive bumps 820 and a sealing member 850 may be substantially the same as the conductive bumps 720 and the sealing member 740 in FIG. 15A, respectively.

In some example embodiments, with respect to each of the memory chips CHP1, CHP2 and CHP3, the plurality of TSVs 830 may be arranged at the same locations in each memory chip. As such, the memory chips CHP1, CHP2 and CHP3 may be stacked such that the plurality of TSVs 830 of each memory chip may be completely overlapped (e.g., arrangements of the plurality of TSVs 830 may be perfectly matched in the memory chips CHP1, CHP2 and CHP3). In such stacked state, the memory chips CHP1, CHP2 and CHP3 may be electrically connected to one another and the base substrate 810 through the plurality of TSVs 830 and conductive material 840.

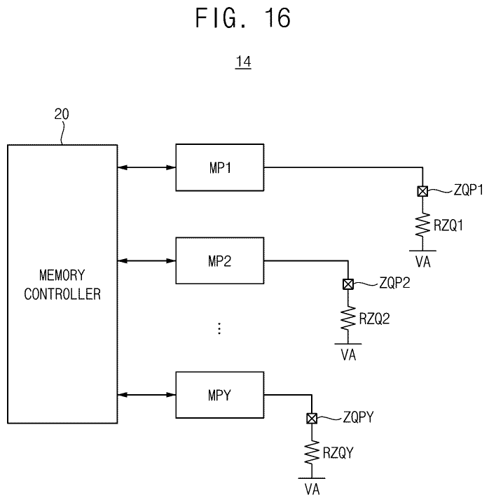

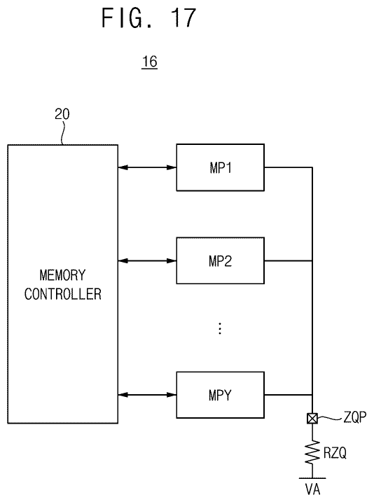

FIGS. 16 and 17 are block diagrams illustrating a memory system according to example embodiments. The descriptions repeated with or overlapping with descriptions of FIG. 14 will be omitted in the interest of brevity.

Referring to FIG. 16, a memory system 14 includes a memory controller 20 and a plurality of memory packages MP1, MP2, . . . , MPY.

Each of the plurality of memory packages MP1, MP2, . . . , MPY may be the memory package according to example embodiments. For example, the plurality of memory packages MP1, MP2, . . . , MPY may include first to Y-th memory packages MP1, MP2, . . . , MPY, where Y is a positive integer greater than or equal to two.

In some example embodiments, ZQ calibration circuits included in the plurality of memory packages MP1, MP2, . . . , MPY may be connected to different ZQ pads ZQP1, ZQP2, . . . , ZQPY and different ZQ resistors RZQ1, RZQ2, . . . , RZQY. For example, first ZQ calibration circuits included in the first memory package MP1 may be connected to the first ZQ pad ZQP1 and the first ZQ resistor RZQ1, second ZQ calibration circuits included in the second memory package MP2 may be connected to the second ZQ pad ZQP2 and the second ZQ resistor RZQ2, and Y-th ZQ calibration circuits included in the Y-th memory package MPY may be connected to the Y-th ZQ pad ZQPY and the Y-th ZQ resistor RZQY.

Referring to FIG. 17, a memory system 16 includes a memory controller 20 and a plurality of memory packages MP1, MP2, . . . , MPY. The descriptions repeated with or overlapping with descriptions of FIG. 16 will be omitted in the interest of brevity.

In some example embodiments, ZQ calibration circuits included in the plurality of memory packages MP1, MP2, . . . , MPY may be commonly connected to the same ZQ pad ZQP and the same ZQ resistor RZQ.

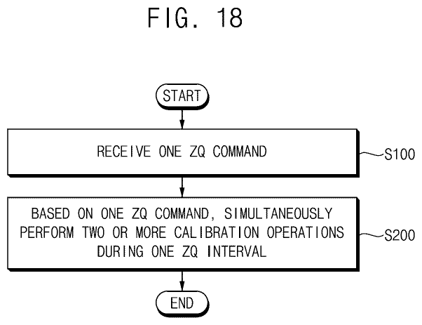

FIG. 18 is a flowchart illustrating a method of operating a ZQ calibration circuit according to example embodiments.

Referring to FIG. 18, in a method of operating a ZQ calibration circuit according to example embodiments, one ZQ command is received (operation S100). Based on the one ZQ command, two or more calibration operations are substantially simultaneously performed during one ZQ interval (operation S200).

As described above, the ZQ calibration circuit according to example embodiments may include two or more ZQ drivers that operate based on different power supply voltages and are implemented with the stacked structure, may include two or more ZQ calibrators for controlling two or more ZQ drivers, and may substantially simultaneously perform two or more calibration operations using two or more ZQ drivers and two or more ZQ calibrators. Accordingly, two or more ZQ calibration operations may be performed rapidly and efficiently without increasing the execution time.

As will be appreciated by those skilled in the art, the inventive concept may be embodied as a system, method, computer program product, and/or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain or store a program for use by or in connection with an instruction execution system, apparatus, or device. For example, the computer readable medium may be a non-transitory computer readable medium.

The example embodiments may be applied to various electronic devices and systems that include the memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A ZQ calibration circuit comprising:
a first ZQ driver connected between a first voltage and a first node, an impedance of the first ZQ driver being adjusted based on a first calibration code;
a first ZQ calibrator connected to the first node, the first ZQ calibrator configured to receive a first reference voltage and generate the first calibration code by performing a first calibration operation based on a voltage at the first node and the first reference voltage;
a second ZQ driver connected between the first node and a ZQ pad, an impedance of the second ZQ driver being adjusted based on a second calibration code; and
a second ZQ calibrator connected to the ZQ pad, the second ZQ calibrator configured to receive a second reference voltage different from the first reference voltage and generate the second calibration code by performing a second calibration operation based on a voltage at the ZQ pad and the second reference voltage, and
wherein the first calibration operation and the second calibration operation are simultaneously performed.

2. The ZQ calibration circuit of claim 1, wherein the first calibration operation and the second calibration operation are simultaneously performed during a single ZQ interval in response to a single ZQ command.

3. The ZQ calibration circuit of claim 2, wherein, during the single ZQ interval, at least a portion of an interval in which the first calibration operation is performed overlaps with at least a portion of an interval in which the second calibration operation is performed.

4. The ZQ calibration circuit of claim 1, wherein the first voltage is a first power supply voltage, and
wherein the first ZQ driver is configured to operate based on the first power supply voltage.

5. The ZQ calibration circuit of claim 4, wherein the first ZQ driver includes:
a plurality of first transistors connected in parallel between the first power supply voltage and the first node, each of the plurality of first transistors configured to be turned on and off based on the first calibration code.

6. The ZQ calibration circuit of claim 5, wherein the plurality of first transistors are p-type metal oxide semiconductor (PMOS) transistors.

7. The ZQ calibration circuit of claim 4, wherein the second ZQ driver is configured to operate based on a second power supply voltage having a voltage level lower than that of the first power supply voltage and equal to that of the first reference voltage.

8. The ZQ calibration circuit of claim 7, wherein the second ZQ driver includes:
a plurality of second transistors connected in parallel between the first node and the ZQ pad, each of the plurality of second transistors configured to be turned on and off based on the second calibration code.

9. The ZQ calibration circuit of claim 8, wherein the plurality of second transistors are n-type metal oxide semiconductor (NMOS) transistors.

10. The ZQ calibration circuit of claim 8, wherein the plurality of second transistors are PMOS transistors.

11. The ZQ calibration circuit of claim 1, wherein the first voltage is a ground voltage, and
wherein the first ZQ driver is configured to operate based on a first power supply voltage having a voltage level equal to that of the first reference voltage.

12. The ZQ calibration circuit of claim 11, wherein the second ZQ driver is configured to operate based on a second power supply voltage having a voltage level equal to that of the second reference voltage.

13. The ZQ calibration circuit of claim 1, further comprising:
a third ZQ driver connected between the first voltage and the first ZQ driver, an impedance of the third ZQ driver being adjusted based on a third calibration code; and
a third ZQ calibrator connected to a second node between the first ZQ driver and the third ZQ driver, the third ZQ calibrator configured to receive a third reference voltage and generate the third calibration code by performing a third calibration operation based on a voltage at the second node and the third reference voltage, and
wherein the first calibration operation, the second calibration operation and the third calibration operation are simultaneously performed.

14. The ZQ calibration circuit of claim 1, wherein the ZQ pad is connected to a ZQ resistor located outside the ZQ calibration circuit, and
wherein the ZQ resistor is connected between the ZQ pad and a second voltage.

15. The ZQ calibration circuit of claim 1, wherein the first ZQ driver and the second ZQ driver are connected in series between the first voltage and the ZQ pad.

16. A memory device comprising:
a memory cell array;
a first pad and a second pad configured to input and output a first signal and a second signal, respectively, the first signal and the second signal being used to operate the memory cell array; and
a ZQ calibration circuit configured to perform a ZQ calibration operation on the first pad and the second pad,
wherein the ZQ calibration circuit includes:
a first ZQ driver connected between a first voltage and a first node, an impedance of the first ZQ driver being adjusted based on a first calibration code;
a first ZQ calibrator connected to the first node, the first ZQ calibrator configured to receive a first reference voltage and generate the first calibration code by performing a first calibration operation based on a voltage at the first node and the first reference voltage;
a second ZQ driver connected between the first node and a ZQ pad, an impedance of the second ZQ driver being adjusted based on a second calibration code; and
a second ZQ calibrator connected to the ZQ pad, the second ZQ calibrator configured to receive a second reference voltage different from the first reference voltage and generate the second calibration code by performing a second calibration operation based on a voltage at the ZQ pad and the second reference voltage, and
wherein the first calibration operation and the second calibration operation are simultaneously performed.

17. The memory device of claim 16, further comprising:
a first driver connected to the first pad, the first driver configured to drive the first signal; and
a second driver connected to the second pad, the second driver configured to drive the second signal.

18. The memory device of claim 17, wherein the first driver has a configuration same as that of the first ZQ driver, and an impedance of the first driver is adjusted based on the first calibration code, and
wherein the second driver has a configuration same as that of the second ZQ driver, and an impedance of the second driver is adjusted based on the second calibration code.

19. The memory device of claim 16, wherein the first signal is based on a first interface, and
wherein the second signal is based on a second interface different from the first interface.

20. A ZQ calibration circuit comprising:
a first ZQ driver configured to operate based on a first power supply voltage, an impedance of the first ZQ driver being adjusted based on a first calibration code, the first ZQ driver including a plurality of first transistors connected in parallel between the first power supply voltage and a first node;
a first ZQ calibrator connected to the first node, the first ZQ calibrator configured to receive a first reference voltage and generate the first calibration code by performing a first calibration operation based on a voltage at the first node and the first reference voltage;
a second ZQ driver configured to operate based on a second power supply voltage having a voltage level lower than a voltage level of the first power supply voltage and equal to a voltage level of the first reference voltage, an impedance of the second ZQ driver being adjusted based on a second calibration code, the second ZQ driver including a plurality of second transistors connected in parallel between the first node and a ZQ pad; and
a second ZQ calibrator connected to the ZQ pad, the second ZQ calibrator configured to receive a second reference voltage different from the first reference voltage and generate the second calibration code by performing a second calibration operation based on a voltage at the ZQ pad and the second reference voltage,
wherein, when the first calibration operation is performed, the impedance of the first ZQ driver is adjusted by controlling on and off states of each of the plurality of first transistors such that a voltage level at the first node and the voltage level of the first reference voltage are equal to each other,
wherein, when the second calibration operation is performed, the impedance of the second ZQ driver is adjusted by controlling on and off states of each of the plurality of second transistors such that a voltage level at the ZQ pad and a voltage level of the second reference voltage are equal to each other, and
wherein the first calibration operation and the second calibration operation are simultaneously performed during a single ZQ interval in response to a single ZQ command.
